(19) United States
(12) Patent Application Publication
(10) Pub. No.: US 2008/0045020 A1
(43) Pub. Date: Feb. 21, 2008

(54) Slurry Composition For a Chemical Mechanical Polishing Process, Method of Polishing an Object Layer and Method of Manufacturing a Semiconductor Memory Device Using the Slurry Composition

(76) Inventors: Nam-Soo Kim, Suwon-si (KR); Jong-Woo Kim, Seoul (KR); Hyo-Sun Lee, Bupyeong-gu (KR); Dong-Jun Lee, Seoul (KR); Bong-Su Ahn, Seoul (KR)

Correspondence Address: F. CHAU & ASSOCIATES, LLC, 130 Woodbury Road, Woodbury, NY, 11797, US

(21) Appl. No.: 11/837,840

(22) Filed: Aug. 13, 2007

(30) Foreign Application Priority Data
Aug. 16, 2006 (KR) 2006-77000

(51) Int. Cl. H01L 21/302; C09K 13/00

(52) U.S. Cl. 438/693; 252/79.1

(57) ABSTRACT

A slurry composition for a chemical mechanical processing process includes about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to about 1.0 percent by weight of a salt of polyacrylic acid having an average molecular weight substantially greater than a molecular weight of the anionic surfactant, and a remainder of water. In addition, a method of polishing an object layer and a method of manufacturing a semiconductor device using the slurry composition are also provided.

### CROSS-REFERENCE TO RELATED APPLICATIONS

This application claims priority under 35 U.S.C. § 119 to Korean Patent Application No. 2006-77000, filed on Aug. 16, 2006, the contents of which are hereby incorporated by reference herein in its entirety.

### BACKGROUND OF THE INVENTION

1. Technical Field

The present invention relates to slurry compositions, methods of polishing an object layer and methods of manufacturing a semiconductor memory device using the slurry composition. More particularly, the present invention relates to slurry compositions for a chemical mechanical polishing process, methods of polishing an object layer and methods of manufacturing a semiconductor memory device using the slurry composition.

2. Description of the Related Art

In manufacturing a semiconductor memory device, structures having a level upper face may be formed on a semiconductor substrate. The structures are generally formed by performing several processes such as a deposition process, a patterning process, an etching process, a polishing process, etc. For example, a chemical mechanical polishing (CMP) process is frequently used for forming the structures.

In the CMP process, a semiconductor substrate to be polished is located on a wafer carrier, and then a slurry composition including an abrasive is provided to a polishing pad. While the semiconductor substrate is in contact with the polishing pad, the semiconductor substrate and the polishing pad are rotated together and pressurized. As a result, a surface of the semiconductor substrate is planarized. For example, the surface of the semiconductor substrate is mechanically polished by rubbing the surface of the semiconductor substrate with the abrasive included in the slurry composition and a rugged surface of the polishing pad. Simultaneously, the surface of the semiconductor substrate is chemically polished by reacting chemical components of the slurry composition with surface substances of the semiconductor substrate.

The polishing efficiency of the CMP process may be determined by, for example, a CMP apparatus, a chemical composition of the slurry composition, or a type of the polishing pad. It is noted that the chemical composition of the slurry composition may have a significant effect on the polishing efficiency.

A single slurry composition may exhibit different polishing rates between various layers in accordance with the properties or types of layers to be polished. Thus, one type of layer may be selectively polished from the other types of layers. For example, one of an oxide layer, a nitride layer, a polysilicon layer and a metal layer, which are widely used in manufacturing a semiconductor device, may be selectively polished by the CMP process due to the differences in the polishing rates of each of these layers.

Slurry compositions, which have a relatively high polishing rate for an oxide layer but a relatively low polishing rate for a silicon nitride layer, have been widely used. The slurry compositions may be classified as a ceria (cerium oxide) slurry composition or a silica slurry composition according to the type of abrasive that is included in the slurry compositions. The ceria slurry composition may have better polishing characteristics than those of the silica slurry composition, and may reduce damages to the polishing pad. However, the manufacturing cost of the ceria slurry composition may be about four times greater than the manufacturing cost of the silica slurry composition, and thus the ceria slurry composition may not be widely used. Accordingly, slurry compositions, which may maintain enhanced polishing properties of the ceria slurry compositions and which may also be prepared at a low cost, are needed in the art.

### SUMMARY OF THE INVENTION

Exemplary embodiments of the present invention provide slurry compositions for a chemical mechanical polishing (CMP) process that may include about 0.3 or less percent by weight of a ceria abrasive and also have improved polishing characteristics.

Exemplary embodiments of the present invention also provide methods of polishing an object layer using the above-mentioned slurry compositions.

Exemplary embodiments of the present invention also provide methods of manufacturing a semiconductor memory device using the above-mentioned slurry compositions.

In accordance with an exemplary embodiment of the present invention, a slurry composition for a chemical mechanical polishing process includes about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to about 1.0 percent by weight of a salt of polyacrylic acid having an average molecular weight substantially greater than a molecular weight of the anionic surfactant, and a remainder of water.

In accordance with an exemplary embodiment of the present invention, the anionic surfactant may include carboxylic acid, a salt of carboxylic acid, sulfuric ester, a salt of sulfuric ester, sulfonic acid, a salt of sulfonic acid, phosphoric ester, a salt of phosphoric ester, a salt of polyacrylic acid, or a mixture thereof. For example, the anionic surfactant may include an ammonium salt of polyacrylic acid having an average molecular weight of about 2,000 to about 30,000.

In accordance with an exemplary embodiment of the present invention, the slurry composition may include about 0.1 to about 0.2 percent by weight of the ceria abrasive, about 0.008 to about 0.02 percent by weight of the anionic surfactant, about 0.0008 to about 0.002 percent by weight of the polyoxyethylene-based nonionic surfactant, about 0.2 to about 0.9 percent by weight of the salt of polyacrylic acid, and a remainder of water.

In accordance with an exemplary embodiment of the present invention, the salt of polyacrylic acid may include an ammonium salt of polyacrylic acid having an average molecular weight of about 100,000 to about 400,000. In accordance with an exemplary embodiment of the present invention, the slurry composition may have a pH value in a range of about 6 to about 9.

In accordance with an exemplary embodiment of the present invention, a method of polishing an object layer is provided. The method includes forming an object layer on a substrate to cover a polish stop layer. In addition, the method further includes polishing the object layer by bringing the object layer in contact with a polishing pad while a slurry composition is provided to the polishing pad until the polish stop layer is exposed. The slurry composition includes about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to about 1.0 percent by weight of a salt of polyacrylic acid having an average molecular weight substantially greater than a molecular weight of the anionic surfactant, and a remainder of water.

In accordance with exemplary embodiment of the present invention, the polish stop layer may include a silicon nitride layer, and the object layer may include a silicon oxide layer. In accordance with an exemplary embodiment of the present invention, the polishing selectivity between the polish stop layer and the object layer may be in a range of about 1:25 to about 1:40. In accordance with an exemplary embodiment of the present invention, the anionic surfactant may include an ammonium salt of polyacrylic acid having an average molecular weight of about 2,000 to about 30,000. In accordance with an exemplary embodiment of the present invention, the salt of polyacrylic acid may include an ammonium salt of polyacrylic acid having an average molecular weight of about 100,000 to about 400,000.

In accordance with still another exemplary embodiment of the present invention, a method of manufacturing a semiconductor memory device is provided. The method includes forming a nitride layer pattern on a substrate. The method further includes partially etching the substrate using the nitride layer pattern as an etching mask to form a trench at an upper portion of the substrate, forming a silicon oxide layer on the substrate to cover the nitride pattern and to fill up the trench and polishing the silicon oxide layer using a slurry composition until the nitride layer pattern is exposed to thereby form an isolation layer on the substrate. The slurry composition includes about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to 1.0 percent by weight of a salt of polyacrylic acid having an average molecular weight substantially greater than a molecular weight of the anionic surfactant, and a remainder of water. The method further includes forming a structure on the substrate including the isolation layer. The structure includes a gate insulation layer and a conductive pattern.

According to exemplary embodiments of the present invention, although the slurry composition includes about 0.3 or less percent by weight of a ceria abrasive, the slurry composition has a high polishing rate for a silicon oxide layer, and also a significantly low polishing rate for a silicon nitride layer. Accordingly, the slurry composition may be effectively used in a process for polishing a silicon oxide layer using a silicon nitride layer as a polish stop layer. Additionally, the silicon nitride layer may be successively polished to have a uniform surface and a thickness using the slurry composition after the silicon oxide layer is polished using the silicon nitride layer as the polish stop layer. The slurry composition may also be prepared at a cost that is about five times lower than the cost to prepare a conventional ceria slurry composition. Thus, the slurry composition according to exemplary embodiments of the present invention may be widely used in a process for manufacturing a semiconductor memory device.

### BRIEF DESCRIPTION OF THE DRAWINGS

Exemplary embodiments of the present invention can be understood in more detail from the following description when taken in conjunction with the accompanying drawings, in which:

FIG. 1 is a graph illustrating changes in zeta potentials of a silicon oxide layer and a silicon nitride layer according to a variation in pH values;

FIG. 2 is a graph illustrating polishing rates of a silicon oxide layer according to a variation in pH values of slurry compositions and an amount of an additive in accordance with an exemplary embodiment of the present invention;

FIG. 3 is a graph illustrating an amount of large particles according to changes in chemical compositions of slurry compositions prepared in Examples 1 to 6 and Comparative Examples 1 to 3;

FIG. 4 is a graph illustrating polishing rates and polishing selectivities for a silicon oxide layer and a silicon nitride layer according to changes in chemical compositions of slurry compositions prepared in Examples 1 to 6 and Comparative Examples 1 to 3;

FIGS. 5 to 6 are cross-sectional views illustrating a method of polishing an object layer in accordance with an exemplary embodiment of the present invention; and

FIGS. 7 to 13 are cross-sectional views illustrating a method of manufacturing a semiconductor memory device in accordance with an exemplary embodiment of the present invention.

### DETAILED DESCRIPTION OF THE EXEMPLARY EMBODIMENTS OF THE INVENTION

The present invention may, however, be embodied in many different forms and should not be construed as limited to the exemplary embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Slurry Composition

A slurry composition for a chemical mechanical polishing (CMP) process of exemplary embodiments of the present invention is a ceria slurry that includes a much smaller amount of a ceria (cerium oxide) abrasive than that of a slurry composition that has been conventionally used.

Although the slurry composition of exemplary embodiments of the present invention includes a small amount of a ceria abrasive, the polishing selectivity between an object layer and a polish stop layer may not decrease in a CMP process using the slurry composition. Additionally, the slurry composition may suppress a decrease in a polishing rate of the object layer that may be caused by a reduced amount of the ceria abrasive, and simultaneously prevent particles of the ceria abrasive from aggregating with each other. The aggregation of the particles of the ceria abrasive may generate scratches on a polishing pad and an object layer. Herein, the polish stop layer may be, for example, a silicon nitride layer, and the object layer may be, for example, a silicon oxide layer in accordance with an exemplary embodiment of the present invention.

The slurry composition of exemplary embodiments of the present invention includes, for example, a small amount of a ceria abrasive, an anionic surfactant, a nonionic surfactant and a polymer-based additive having a high molecular weight. The polymer-based additive may improve a polishing rate and a polishing selectivity of the slurry composition, and have a molecular weight substantially higher than that of the anionic surfactant.

The slurry composition includes, for example, an amount of the ceria (CeO₂) abrasive, which is about five times less than an amount of the ceria abrasive a included in a conventionally used slurry composition. The ceria abrasive may be an expensive component of the slurry composition. The ceria abrasive may have a high polishing rate for the silicon oxide layer and a low polishing rate for the silicon nitride layer. Therefore, the ceria abrasive may be used, for example, for polishing the silicon oxide layer using the silicon nitride layer as a polish stop layer.

When the slurry composition includes less than about 0.05 percent by weight of the ceria abrasive based on a total weight of the slurry composition, a polishing efficiency of a process performed for polishing the silicon oxide layer may fall sharply, and particles of the ceria abrasive may aggregate with each other. In addition, when the amount of the ceria abrasive is greater than about 0.3 percent, the slurry composition may not be prepared with a cost that is about five times lower than a cost spent for preparing the conventionally used ceria slurry. Therefore, the slurry composition may include about 0.05 to about 0.3 percent by weight of the ceria abrasive. In accordance with an exemplary embodiment of the present invention, the slurry composition may include about 0.1 to about 0.2 percent by weight of the ceria abrasive.

Additionally, a particle size and an amount of the ceria abrasive included in the slurry composition may influence the polishing efficiency of a polishing process. For example, when the particle size of the ceria abrasive is too large, a polishing rate of the silicon oxide layer may increase, and a stress applied to the polish stop layer such as the silicon nitride layer may simultaneously increase in the polishing process. Then, grains composing a surface of the silicon nitride layer may be partially separated from the silicon nitride layer.

As the particle size of the ceria abrasive decreases, damage to the silicon nitride layer may be reduced. However, the surface roughness of the silicon nitride layer may be deteriorated after performing the polishing process. Additionally, the polishing rate of the silicon oxide layer may also decrease. Therefore, the ceria abrasive may preferably have a particle size of about 50 nanometers (nm) to about 400 nm, and more preferably a particle size of about 120 nm to about 200 nm.

The slurry composition includes an anionic surfactant as a first dispersing agent. The anionic surfactant may inhibit particles of the ceria abrasive from aggregating with each other in the slurry composition, and thus a polishing efficiency of the slurry composition may be improved. Examples of the anionic surfactant may include but are not limited to carboxylic acid, a salt of carboxylic acid, sulfuric ester, a salt of sulfuric ester, sulfonic acid, a salt of sulfonic acid, phosphoric ester, a salt of phosphoric ester, a salt of polyacrylic acid, or a mixture thereof.

In accordance with an exemplary embodiment of the present invention, the anionic surfactant may include, for example, a salt of polyacrylic acid. An example of the salt of polyacrylic acid may include but is not limited to an ammonium salt of polyacrylic acid having an average molecular weight of about 2,000 to about 30,000. The ammonium salt of polyacrylic acid may be prepared by, for example, a neutralization reaction of polyacrylic acid and ammonia. Then, the ammonium salt of polyacrylic acid may have a pH value of about 7 to about 9 when dissolving into water.

Moreover, the anionic surfactant may be adsorbed onto the particles of the ceria abrasive to enhance dispersibility of the ceria abrasive in the slurry composition by using, for example, electrostatic repulsion and steric hindrance. The enhanced dispersibility of the ceria abrasive in the slurry composition may prevent the particles of the ceria abrasive from aggregating with each other. Furthermore, the anionic surfactant may increase viscosity of the slurry composition, to thereby reduce the noise in the polishing process.

When the slurry composition includes less than about 0.005 percent by weight of the anionic surfactant, the dispersibility of the ceria abrasive in the slurry composition may decrease, and thus the particles of the ceria abrasive may aggregate with each other. In addition, when an amount of the anionic surfactant is greater than about 0.04 percent by weight, the viscosity of the slurry composition may increase, and thus foam may be generated from the slurry composition by the polishing process and an edge portion of the object layer may be polished faster than other portions of the object layer. Therefore, the slurry composition may include about 0.005 to about 0.04 percent by weight of the anionic surfactant. In D accordance with an exemplary embodiment of the present invention, the slurry composition may preferably include about 0.008 to about 0.02 percent by weight of the anionic surfactant.

The slurry composition also includes a polyoxyethylene-based nonionic surfactant as a second dispersing agent. The polyoxyethylene-based nonionic surfactant may include a hydrophobic portion and a hydrophilic portion. The hydrophilic portion of the polyoxyethylene-based nonionic surfactant may be combined with the anionic surfactant adsorbed onto the particles of the ceria abrasive to form a passivation layer on the particles of the ceria abrasive. The passivation layer on the particles of the ceria abrasive may inhibit an aggregation of the particles of the ceria abrasive and may suppress the formation of large abrasive particles. Additionally, the polyoxyethylene-based nonionic surfactant may maintain the polishing selectivity between the silicon nitride layer and the silicon oxide layer in the polishing process.

When the slurry composition includes less than about 0.0005 percent by weight of the polyoxyethylene-based nonionic surfactant based on a total weight of the slurry composition, large abrasive particles may be generated in the slurry composition while the silicon oxide layer is polished using the slurry composition. In addition, when an amount of the polyoxyethylene-based nonionic surfactant is greater than about 0.003 percent by weight, foam may be generated from the slurry composition. Therefore, the slurry composition may include about 0.0005 to about 0.003 percent by weight of the polyoxyethylene-based nonionic surfactant. In accordance with an exemplary embodiment of the present invention, the slurry composition may preferably include about 0.0008 to about 0.002 percent by weight of the polyoxyethylene-based nonionic surfactant.

Examples of the polyoxyethylene-based nonionic surfactant may include but are not limited to polyoxyethylene lauryl ether, polyoxyethylene cetyl ether, polyoxyethylene oleyl ether, polyoxyethylene sorbitan monolaurate, polyoxyethylene isooctylphenyl ether, or mixtures thereof.

In accordance with an exemplary embodiment of the present invention, polyoxyethylene lauryl ether such as, for example, Brij 35 (a trade name manufactured by ICI Americas, Inc.) may have a chemical structure represented by Formula (1),

C₁₂H₂₅(OCH₂CH₂)ₙOH (1)

wherein n represents an integer ranging from 20 to 25.

In accordance with an exemplary embodiment of the present invention, polyoxyethylene oleyl ether such as, for example, Brij 97 (a trade name manufactured by ICI Americas, Inc.) may have a chemical structure represented by Formula (2),

C₁₈H₃₅(OCH₂CH₂)ₙOH (2)

wherein n represents an integer ranging from 8 to 12.

In accordance with an exemplary embodiment of the present invention, polyoxyethylene isooctylphenyl ether such as, for example, Triton X-100 (a trade name manufactured by Union Carbide Corp.) may have a chemical structure represented by Formula (3),

4-(C₈H₁₇)C₆H₄(OCH₂CH₂)ₙOH (3)

wherein n represents an integer ranging from 8 to 12.

In accordance with an exemplary embodiment of the present invention, polyoxyethylene isooctylphenyl ether such as, for example, Triton X-405 (a trade name manufactured by Union Carbide Corp.) may have a chemical structure represented by Formula (4),

4-(C₈H₁₇)C₆H₄(OCH₂CH₂)ₙOH (4)

wherein n represents an integer ranging from 35 to 45.

In accordance with an exemplary embodiment of the present invention, examples of polyoxyethylene sorbitan monolaurate may include, but are not limited to Tween 20 and Tween 80 (trade names manufactured by Uniqema).

The slurry composition of exemplary embodiments of the present invention includes a polymer-based additive having a molecular weight substantially higher than that of the anionic surfactant. In accordance with an exemplary embodiment of the present invention, the polymer-based additive may include, for example, an ammonium salt of polyacrylic acid having an average molecular weight of about 100,000 to about 400,000. The ammonium salt of polyacrylic acid may be prepared by, for example, reacting polyacrylic acid with ammonium hydroxide. The ammonium salt of polyacrylic acid may have a pH value of about 7 to about 9 when dissolving in water. The ammonium salt of polyacrylic acid used as the polymer-based additive may be selectively adsorbed onto a silicon nitride layer having a positive zeta potential to thereby protect the silicon nitride layer and decrease the polishing rate of the silicon nitride layer in the CMP process, because the ammonium salt of polyacrylic acid may have an anionic property. For example, the adsorbed ammonium salt of polyacrylic acid may increase the thickness of the silicon nitride layer. As a result, the silicon nitride layer may be less polished by the CMP process.

When the slurry composition includes less than about 0.2 percent by weight of the salt of polyacrylic acid having an average molecular weight substantially greater than a molecular weight of the anionic surfactant, polishing rates of both the silicon oxide layer and the silicon nitride layer may increase, and thus the slurry composition may not have a sufficiently high polishing selectivity of the silicon oxide layer relative to the silicon nitride layer. Additionally, when an amount of the salt of high molecular weight polyacrylic acid is greater than about 1.0 percent by weight, the polishing rate of the silicon oxide layer may decrease greatly. Therefore, the slurry composition may include about 0.2 to about 1.0 percent by weight of the salt of polyacrylic acid having a high molecular weight. In accordance with an exemplary embodiment of the present invention, the slurry composition may preferably include about 0.2 to about 0.9 percent by weight of the salt of polyacrylic acid.

When the average molecular weight of the ammonium salt of polyacrylic acid is less than about 100,000, the thickness of the silicon nitride layer may not substantially increase. Additionally, when the average molecular weight of the ammonium salt of polyacrylic acid is greater than about 400,000, the polishing rate of the silicon oxide layer may decrease. Therefore, the ammonium salt of polyacrylic acid may have an average molecular weight ranging from about 100,000 to about 400,000, and preferably ranging from about 150,000 to about 300,000.

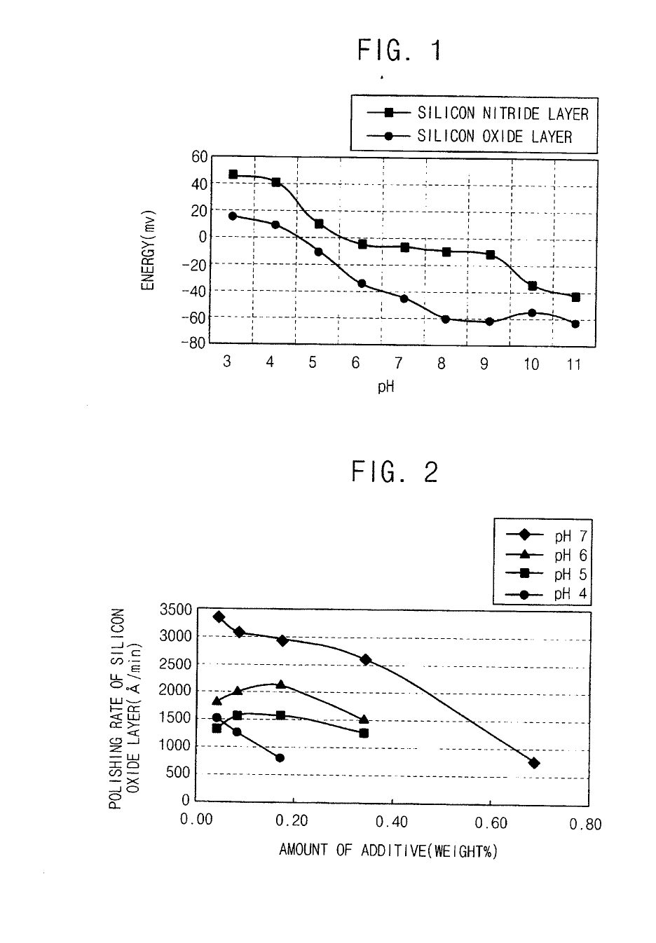

FIG. 1 is a graph illustrating changes in zeta potentials of a silicon oxide layer and a silicon nitride layer according to a variation of pH values. In FIG. 1, a first graph indicated with plurality of () symbols shows a zeta potential of a silicon oxide layer, and a second graph indicated with plurality of (▪) symbols denotes a zeta potential of a silicon nitride layer.

Referring to FIG. 1, the silicon oxide layer to be polished and the silicon nitride layer used as a polish stop layer have different zeta potentials, because the silicon oxide layer and the silicon nitride layer have different surface properties. Particularly, when a pH value is about 5 or higher, both the silicon oxide layer and the silicon nitride layer have negative zeta potentials. When the pH value is in a range of about 7 to about 9, a difference in negative zeta potentials between the silicon oxide layer and the silicon nitride layer becomes obvious. Accordingly, a slurry composition having a pH value in a range of about 7 to about 9 may be preferably used to increase the polishing rate of the silicon oxide layer and simultaneously reduce the polishing rate of the silicon nitride layer.

The slurry composition of exemplary embodiments of the present invention includes water as a solvent. When the slurry composition includes less than about 98.644 percent by weight of water, viscosity of the slurry composition may increase, and thus a CMP apparatus may be damaged in the CMP process using the slurry composition. Additionally, when an amount of water is greater than about 99.297 percent by weight, the viscosity of the slurry composition may decrease, and thus a mechanical polishing efficiency may be reduced greatly.

In accordance with an exemplary embodiment of the present invention, the slurry composition may be prepared by mixing the ceria abrasive, the first dispersing agent, a first solution including the second dispersing agent, and a second solution including the additive such as, for example, the salt of polyacrylic acid having a high molecular weight.

The slurry composition having the above-mentioned chemical composition may include a ceria abrasive, which has an amount of about five times smaller than an amount of a ceria abrasive included in a conventionally used ceria slurry composition that includes more than about 0.7 percent by weight of the ceria abrasive. Accordingly, the manufacturing cost of the slurry composition may be significantly reduced.

Evaluation of Polishing Rates According to Changes in a pH Value and an Amount of an Additive

For evaluating the polishing rates of a silicon oxide layer according to a changes in a pH value of a slurry composition and an amount of a salt of polyacrylic acid having a high molecular weight, slurry compositions having chemical compositions as shown in Table 1 were prepared. A substrate including an oxide layer formed thereon was polished using one of the slurry compositions. An amount of a ceria abrasive was about 0.12 percent by weight, and an ammonium salt of polyacrylic acid having a molecular weight of about 250,000 was used. Polishing conditions include about 103 rotations per minute (rpm) of a rotational speed of a platen, about 97 rpm of a rotational speed of a head, about 4 pounds per square inch (psi) of a down force pressure, and about 1.5 psi of a back pressure.

TABLE 1

| | Polishing Rate of | | | | |
|---|---|---|---|---|---|
| Additive | Silicon Oxide Layer (Å/min) | | | | |
| (Weight %) | 0.04 | 0.09 | 0.17 | 0.34 | 0.69 |
| pH 4.0 | 1496 | 1242 | 788 | — | — |
| pH 5.0 | 1306 | 1564 | 1563 | 1278 | — |
| pH 6.0 | 1812 | 1993 | 2088 | 1508 | — |
| pH 7.0 | 3301 | 3037 | 2909 | 2604 | 780 |

FIG. 2 is a graph illustrating polishing rates of the silicon oxide layer according to changes in the pH values of the slurry composition and the amounts of the additive.

Referring to FIG. 2, when the pH value of the slurry composition was about 4.0, the polishing rate of the silicon oxide layer tended to decrease sharply from 1,496 angstroms (Å)/min as the amount of the ammonium salt of high molecular weight polyacrylic acid increased. Additionally, when the pH value of the slurry composition was about 5.0 or about 6.0, the polishing rate of the silicon oxide layer tended to increase as the amount of the ammonium salt of polyacrylic acid increased from about 0.04 percent by weight to about 0.17 percent by weight. However, the polishing rate of the silicon oxide layer tended to decrease abruptly, as the amount of the ammonium salt of polyacrylic acid increased from about 0.17 percent by weight to about 0.69 percent by weight. Moreover, when the pH value of the slurry composition was about 7.0, the polishing rate of the silicon oxide layer tended to decrease gradually from 3,301 Å/min as the amount of the ammonium salt of polyacrylic acid increased.

From the evaluation result, it was noted that the polishing rate of the silicon oxide layer was more dependent on the pH value of the slurry composition than the amount of the ammonium salt of polyacrylic acid. For example, when the pH value of the slurry composition was lower than about 7.0, the polishing rate of the silicon oxide layer was not sufficient despite the addition of the ammonium salt of polyacrylic acid. Therefore, it may be confirmed that the pH value of the slurry composition may be preferably in a range of about 7 to about 9.

Preparation of Slurry Compositions

### EXAMPLE 1

A slurry composition was prepared by mixing about 0.12 percent by weight of a ceria abrasive, about 0.0082 percent by weight of ammonium salt of polyacrylic acid having an average molecular weight of about 5,000 as a first dispersing agent, about 0.00025 percent by weight of a polyoxyethylene-based nonionic surfactant as a second dispersing agent, about 0.5 percent by weight of ammonium salt of polyacrylic acid having an average molecular weight of about 250,000 as an additive, and a remainder of water.

### EXAMPLE 2

A slurry composition was prepared by mixing about 0.12 percent by weight of a ceria abrasive, about 0.0082 percent by weight of ammonium salt of polyacrylic acid having an average molecular weight of about 5,000 as a first dispersing agent, about 0.0005 percent by weight of a polyoxyethylene-based nonionic surfactant as a second dispersing agent, about 0.5 percent by weight of ammonium salt of polyacrylic acid having an average molecular weight of about 250,000 as an additive, and a remainder of water.

### EXAMPLE 3

A slurry composition was prepared by mixing about 0.12 percent by weight of a ceria abrasive, about 0.0082 percent by weight of ammonium salt of polyacrylic acid having an average molecular weight of about 5,000 as a first dispersing agent, about 0.001 percent by weight of a polyoxyethylene-based nonionic surfactant as a second dispersing agent, about 0.5 percent by weight of ammonium salt of polyacrylic acid having an average molecular weight of about 250,000 as an additive, and a remainder of water.

### EXAMPLE 4

A slurry composition was prepared by mixing about 0.12 percent by weight of a ceria abrasive, about 0.0125 percent by weight of ammonium salt of polyacrylic acid having an average molecular weight of about 5,000 as a first dispersing agent, about 0.00025 percent by weight of a polyoxyethylene-based nonionic surfactant as a second dispersing agent, about 0.5 percent by weight of ammonium salt of polyacrylic acid having an average molecular weight of about 250,000 as an additive, and a remainder of water.

### EXAMPLE 5

A slurry composition was prepared by mixing about 0.12 percent by weight of a ceria abrasive, about 0.0125 percent by weight of ammonium salt of polyacrylic acid having an average molecular weight of about 5,000 as a first dispersing agent, about 0.0005 percent by weight of a polyoxyethylene-based nonionic surfactant as a second dispersing agent, about 0.5 percent by weight of ammonium salt of polyacrylic acid having an average molecular weight of about 250,000 as an additive, and a remainder of water.

### EXAMPLE 6

A slurry composition was prepared by mixing about 0.12 percent by weight of a ceria abrasive, about 0.0125 percent by weight of ammonium salt of polyacrylic acid having an average molecular weight of about 5,000 as a first dispersing agent, about 0.001 percent by weight of a polyoxyethylene-based nonionic surfactant as a second dispersing agent, about 0.5 percent by weight of ammonium salt of polyacrylic acid having an average molecular weight of about 250,000 as an additive, and a remainder of water.

### COMPARATIVE EXAMPLE 1

A slurry composition was prepared by mixing about 0.12 percent by weight of a ceria abrasive, about 0.0082 percent by weight of ammonium salt of polyacrylic acid having an average molecular weight of about 5,000 as a first dispersing agent, about 0.5 percent by weight of ammonium salt of polyacrylic acid having an average molecular weight of about 250,000 as an additive, and a remainder of water.

### COMPARATIVE EXAMPLE 2

A slurry composition was prepared by mixing about 0.12 percent by weight of a ceria abrasive, about 0.0125 percent by weight of ammonium salt of polyacrylic acid having an average molecular weight of about 5,000 as a first dispersing agent, about 0.5 percent by weight of ammonium salt of polyacrylic acid having an average molecular weight of about 250,000 as an additive, and a remainder of water.

### COMPARATIVE EXAMPLE 3

A slurry composition was prepared by mixing about 0.12 percent by weight of a ceria abrasive, about 0.0164 percent by weight of ammonium salt of polyacrylic acid having an average molecular weight of about 5,000 as a first dispersing agent, about 0.5 percent by weight of ammonium salt of polyacrylic acid having an average molecular weight of about 250,000 as an additive, and a remainder of water.

The first dispersing agent used in Examples 1 to 6 and Comparative Examples 1 to 3 was ammonium salt of polyacrylic acid having an average molecular weight of about 5,000. The polyoxyethylene-based nonionic surfactant used as the second dispersing agent in Examples 1 to 6 was polyoxyethylene sorbitan monolaurate. The additive used in Examples 1 to 6 and Comparative Examples 1 to 3 was ammonium salt of polyacrylic acid having an average molecular weight of about 250,000.

Evaluation of Amount of Large Particles in Slurry Composition

An amount of large particles, each of which had an average diameter larger than about 2 micrometers (μm) and was generated in the slurry compositions prepared in Examples 1 to 6 and Comparative Examples 1 to 3, was evaluated. The large particles may be formed by an aggregation of the ceria abrasive.

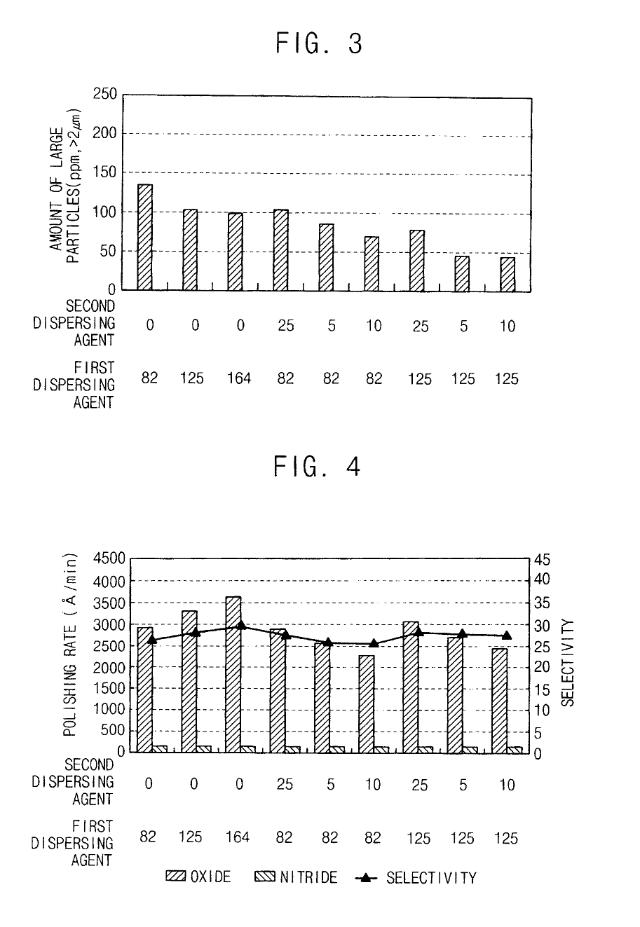

FIG. 3 is a graph illustrating changes in an amount of large particles according to changes in chemical compositions of the slurry composition prepared in Examples 1 to 6 and Comparative Examples 1 to 3.

Referring to FIG. 3, the slurry compositions prepared in Examples 1 to 6 included less than about 100 parts per million (ppm) of the large particles. For example, the slurry compositions prepared in Examples 3, 5 and 6 included less than about 60 ppm of the large particles. However, the slurry compositions prepared in Comparative Examples 1 to 3 included more than about 100 ppm of the large particles.

It may be confirmed that the amount of the large particles may be hardly adjusted by changes in the amount of the first dispersing agent, and the amount of the large particles decreases as an amount of the polyoxyethylene-based nonionic surfactant used as the second dispersing agent increases. Accordingly, the slurry composition may preferably include about 5 ppm to about 10 ppm, e.g., about 0.0005 to about 0.001 percent by weight, of the polyoxyethylene-based nonionic surfactant to reduce the generation of the large particles in the slurry composition.

Evaluation of Polishing Selectivity According to Amounts of First and Second Dispersing Agents

For evaluating the polishing rates of a silicon oxide layer and a silicon nitride layer and polishing selectivities between the silicon oxide layer and the silicon nitride layer according to amounts of the anionic surfactant used as the first dispersing agent and the polyoxyethylene-based nonionic surfactant used as the second dispersing agent, substrates including a silicon oxide layer and a silicon nitride layer formed thereon were prepared. A CMP process was performed using one of the slurry compositions prepared in Examples 1 to 6 and Comparative Examples 1 to 3 on the substrates. The CMP process was carried out using Reflextion (a trade name manufactured by AMAT). Polishing conditions of the CMP process included about 103 rpm of a rotational speed of a platen, about 97 rpm of a rotational speed of a head, about 4 psi of a down force pressure, and about 1.5 psi of a back pressure.

FIG. 4 is a graph illustrating polishing rates and polishing selectivities for the silicon oxide layer and the silicon nitride layer according to changes in chemical compositions of the slurry compositions prepared in Examples 1 to 6 and Comparative Examples 1 to 3.

Referring to FIG. 4, the slurry compositions prepared in Examples 1 to 6 had polishing rates for the silicon oxide layer between about 2,200 Å/min and about 3,000 Å/min, and the slurry compositions had low polishing rates for the silicon nitride layer between about 60 Å/min and about 110 Å/min. Additionally, the slurry compositions prepared in Examples 1 to 6 had polishing selectivities between about 1:24 to about 1:28. However, the slurry compositions prepared in Comparative Examples 1 to 3 had relatively high polishing rates for the silicon oxide layer between about 3,000 Å/min and about 3,700 Å/min, and the slurry compositions had relatively low polishing rates for the silicon nitride layer between about 70 Å/min and about 120 Å/min. In addition, the slurry compositions prepared in Comparative Examples 1 to 3 had polishing selectivities between about 1:22 to about 1:30.

Method of Polishing an Object Layer

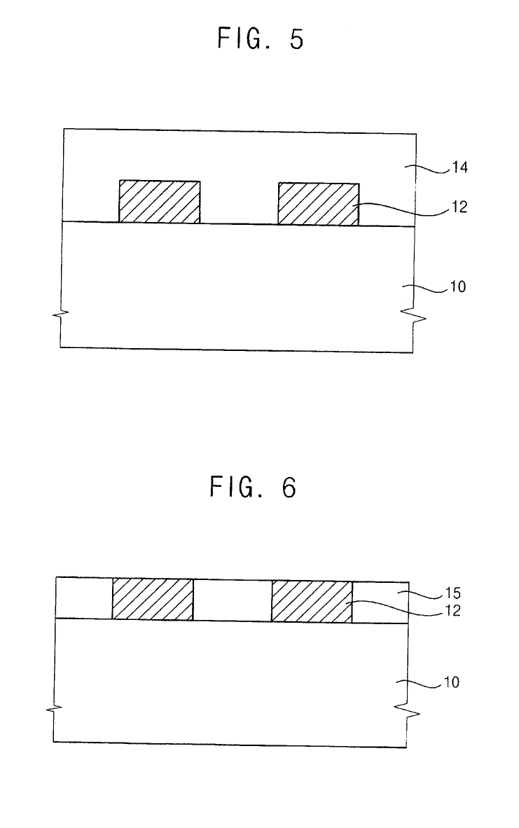

FIGS. 5 to 6 are cross-sectional views illustrating a method of polishing an object layer in accordance with an exemplary embodiment of the present invention.

Referring to FIG. 5, a polish stop layer 12 is formed on a substrate 10. The polish stop layer 12 may be formed directly on the substrate 10, or may be formed on the substrate by interposing a structure such as an electrode, a conductive layer, a conductive layer pattern, an insulation layer or an insulation layer pattern therebetween. The polish stop layer 12 may be formed using, for example, silicon nitride. In accordance with an exemplary embodiment of the present invention, the polish stop layer 12 may be, for example, a nitride layer pattern employed in forming an isolation trench at an upper portion of the substrate 10. In accordance with another exemplary embodiment of the present invention, an opening may be formed through the polish stop layer 12. The opening may expose an underlying structure.

An object layer 14 is formed on the polish stop layer 12. The object layer 14 may be formed using, for example, a hydrophilic material. For example, the object layer 14 may be formed using a silicon oxide. Examples of the silicon oxide may include, but are not limited to, phosphor silicate glass (PSG), borophosphosilicate glass (BPSG), undoped silica glass (USG), spin-on-glass (SOG), tetraethyl orthosilicate (TEOS), plasma enhanced-TEOS (PE-TEOS), high-density plasma chemical vapor deposition (HDP-CVD) oxide, etc. In accordance with an exemplary embodiment of the present invention, the object layer 14 may be formed to have a thickness sufficient for covering the polish stop layer 12.

Referring to FIG. 6, the object layer 14 is chemically and mechanically polished to form an object layer pattern 15 having a level upper face until the polish stop layer 120 is exposed.

For example, a slurry composition including about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to 1.0 percent by weight of a salt of high molecular weight polyacrylic acid having an average molecular weight substantially greater than a molecular weight of the anionic surfactant, and a remainder of water is provided to a polishing pad. The object layer 14 is polished by bringing the object layer 14 in contact with the polishing pad and by rubbing the object layer 14 with the polishing pad so as to partially remove an upper portion of the object layer 14 from the substrate 10. In accordance with an exemplary embodiment of the present invention, the polishing process may be carried out until the polish stop layer 12 is exposed to thereby form the object layer pattern 15 on the substrate 10.

The polishing process may be carried out by rotating the polishing pad and the substrate 10 on which the object layer 14 is formed. In the polishing process, the substrate 10 may make contact with the polishing pad under a pressurized condition. The object layer 14 may be chemically polished by the slurry composition, and mechanically polished by the rotation and the pressurization of the substrate 10 and the polishing pad. The polishing pad and the substrate 10 may be rotated in same directions or in opposite directions. The slurry composition has already been previously described, so any further explanations in this regard will be omitted herein for brevity.

Although the slurry composition includes about 0.3 or less percent by weight of the ceria abrasive, the slurry composition may have a high polishing rate for the object layer 14 including silicon oxide, and also a significantly low polishing rate for the polish stop layer 120 including silicon nitride. In accordance with an exemplary embodiment of the present invention, a pH value of the slurry composition may be in a range of about 7 to about 9, and the slurry composition may have the polishing rate ranging from about 2,500 Å/min to about 3,000 Å/min for a silicon oxide layer. The slurry composition may have a polishing rate ranging from about 50 Å/min to about 110 Å/min for a silicon nitride layer. Here, the slurry composition may have a polishing rate preferably ranging from about 60 Å/min to about 100 Å/min for the silicon nitride layer. Additionally, the slurry composition may prevent the particles of the ceria abrasive from aggregating with each other that may be caused by reducing the amount of the ceria abrasive in the slurry composition, because the slurry composition includes the anionic surfactant, the polyoxyethylene-based nonionic surfactant, and the salt of polyacrylic acid having a high molecular weight.

Accordingly, when the polishing process is performed using the slurry composition on the substrate including the silicon nitride layer as the polish stop layer 12 and the silicon oxide layer as the object layer 14 formed on the silicon nitride layer, the silicon oxide layer may be effectively polished using the silicon nitride layer as a polish stop layer.

Additionally, when the silicon oxide layer is excessively polished using the slurry composition, the thickness loss of the silicon nitride layer may be little, and thus the margin of the CMP process may be enhanced. For example, the anionic surfactant and the nonionic surfactant included in the slurry composition may form a passivation layer on the polish stop layer 12 and particles of the ceria abrasive to thereby prevent or suppress an excessive polishing of the polish stop layer. As a result, the slurry composition may have a low polishing rate for the polish stop layer 12.

In accordance with an exemplary embodiment of the present invention, the above-mentioned method of polishing the object layer may be widely used for manufacturing various structures of a semiconductor device such as, for example, an isolation layer, a gate structure, a wiring structure, a pad structure, a contact, a capacitor, etc.

Method of Manufacturing a Semiconductor Memory Device

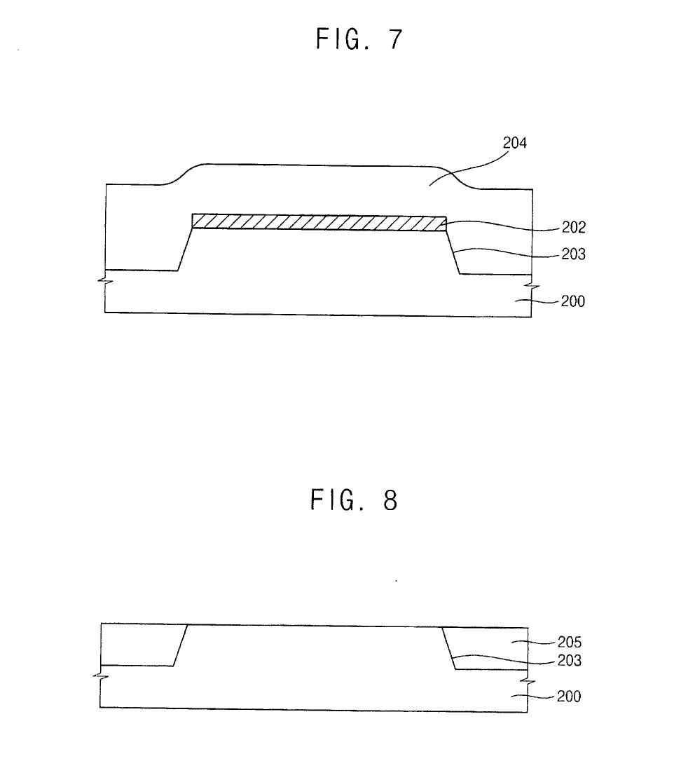

FIGS. 7 to 13 are cross-sectional views illustrating a method of manufacturing a semiconductor memory device in accordance with an exemplary embodiment of the present invention.

Referring to FIG. 7, a silicon oxide layer 204 is formed on a substrate 200 including a trench 203. The trench 203 is formed at an upper portion of the substrate 200. Examples of the substrate 200 may include but are not limited to a silicon wafer, a germanium substrate, a silicon germanium substrate, a silicon-on-insulator (SOI) substrate, etc.

For example, a mask layer may be formed on the substrate 200. The mask layer may be, for example, a silicon nitride layer or a layer having a multi-layered structure including a silicon oxide layer and a silicon nitride layer. For example, the silicon nitride layer may be formed by performing several processes such as a low-pressure chemical vapor deposition (LPCVD) process, a plasma-enhanced chemical vapor deposition (PECVD) deposition, etc. using a dichlorosilane (SiH₂Cl₂) gas, a silane (SiH₄) gas, an ammonium (NH₃) gas, etc.

The mask layer may be partially etched using, for example, a first photoresist pattern as an etching mask by an etching process. Then, the first photoresist pattern may be removed by a stripping process using oxygen plasma. Thus, a mask pattern 202 exposing a portion of the substrate 200 is formed on the substrate 200.

The substrate 200 is partially etched using the mask pattern 202 as an etching mask to thereby form the trench 203 at the upper portion of the substrate 200. The trench 203 may be used for defining an active region and a field region of the substrate 200.

In accordance with exemplary embodiments of the present invention, when the trench 203 is formed at the upper portion of the substrate 200, an oxide layer may be further formed on a sidewall and a bottom of the trench 203 for curing damage to the trench 203. The oxide layer may be formed by, for example, a thermal oxidation process. Additionally, a liner film may be further formed on a sidewall and a bottom of the trench 203. The liner film may prevent impurities generated in subsequent processes from penetrating into the substrate 200 through the trench 203. The liner film may be formed using, for example, nitride and be formed by a chemical vapor deposition (CVD) process.

The silicon oxide layer 204 is formed on the substrate 200 and the mask pattern 202 to fill up the trench 203. For example, the silicon oxide layer 204 may be formed using an oxide such as PSG, BPSG, USG, SOG, TEOS, PE-TEOS, HDP-CVD oxide, etc.

Referring to FIG. 8, an isolation layer 205 is formed to fill up the trench 203. Then, the mask pattern is removed from the substrate 200.

For example, a first CMP process by using a slurry composition may be performed on the silicon oxide layer 204. The first CMP process may be carried out until the mask pattern 202 is exposed. Then, the silicon oxide layer 204 may be formed to fill up the isolation layer 205. The slurry composition includes about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to about 1.0 percent by weight of a salt of polyacrylic acid having an average molecular weight substantially greater than a molecular weight of the anionic surfactant, and a remainder of water. In accordance with an exemplary embodiment of the present invention, a pH value of the slurry composition may be in a range of about 7 to about 9. The slurry composition is previously described, so any further explanations in this regard will be omitted herein for brevity.

When the first CMP process using the slurry composition is performed on the silicon oxide layer 204, the mask pattern 202 having a relative thin thickness may be used as a polish stop layer. Because the anionic surfactant and the polyoxyethylene-based nonionic surfactant included in the slurry composition may form a passivation layer on the surface of the ceria abrasive, the slurry composition may have a low polishing rate for the mask pattern 202.

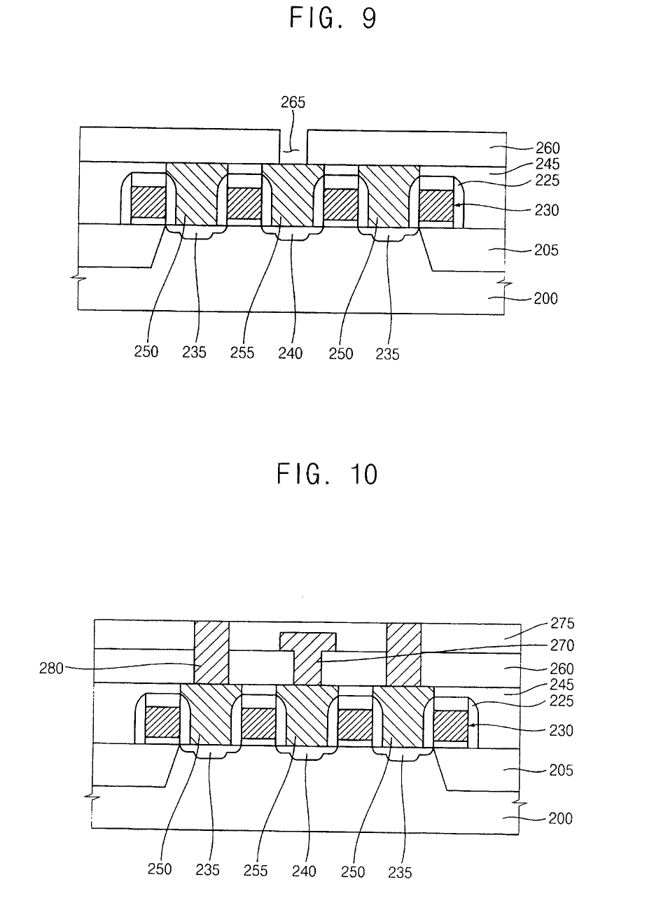

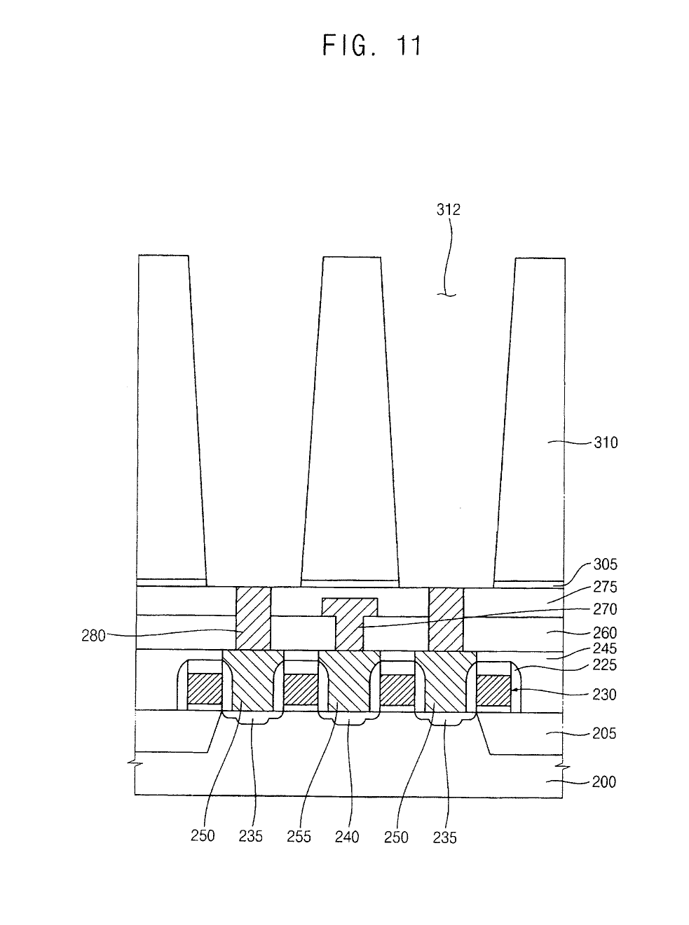

Referring to FIG. 9, a gate insulation layer is formed on the substrate 200. The gate insulation layer may be formed by, for example, a thermal oxidation process, a CVD process or an atomic layer deposition (ALD) process. The gate insulation layer may be formed using, for example, a silicon oxide or a metal oxide having a higher dielectric constant than that of the silicon oxide.

For example, the gate insulation layer may be formed using hafnium oxide, zirconium oxide, tantalum oxide, yttrium oxide, niobium oxide, aluminum oxide, titanium oxide, cerium oxide, indium oxide, ruthenium oxide, magnesium oxide, strontium oxide, boron oxide, tin oxide, lead oxide, vanadium oxide, lanthanum oxide, praseodymium oxide, antimony oxide, calcium oxide, or a combination thereof.

A first conductive layer and a gate mask layer are successively formed on the gate insulation layer. The first conductive layer may be formed using, for example, polysilicon doped with impurities. The first conductive layer may be patterned to form a gate electrode in subsequent processes.

The gate mask layer may be formed using a material having an etching selectivity relative to a first insulating interlayer 245 that is successively formed. For example, the gate mask layer may be formed using a nitride such as silicon nitride when the first insulating interlayer 245 is formed using silicon oxide. A nitride layer may be formed on the first conductive layer. The nitride layer may be partially etched using a second photoresist pattern as an etching mask by a dry-etching process, to thereby form a gate mask on the first conductive layer. The second photoresist pattern may be removed by a stripping process using oxygen plasma.

The first conductive layer and the gate insulation layer are patterned using the gate mask as an etching mask. Thus, gate structures 230 are formed on the substrate 200. Each of the gate structures 230 includes a gate insulation layer pattern, a gate electrode and a gate mask.

A silicon nitride layer is formed on the substrate 200 to cover the gate structures 230. The silicon nitride layer is anisotropically etched to form gate spacers 225 on sidewalls of the gate structures 230.

Impurities are implanted using the gate structures 230 as ion implantation masks into portions of the substrate 200 exposed between the gate structures 230. The implanted impurities are thermally treated to form a first contact region 235 and a second contact region 240 on the substrate 200. The first and the second contact regions 235 and 240 may correspond to source/drain regions.

For example, the first contact region 235 serves as a capacitor contact region with which a first pad 250 may make contact, and the second contact region 240 serves as a bit line contact region with which a second pad 255 may make contact. Accordingly, transistors are formed on the substrate 200. The transistors include the gate structure 230, the gate spacers 225 and the first and second contact regions 235 and 240.

The first insulating interlayer 245 is formed on the substrate 200 to cover the transistors. The first insulating interlayer 245 may be formed using, for example, BPSG, PSG, SOG, PE-TEOS, USG, HDP-CVD oxide, etc. Additionally, the first insulating interlayer 245 may be formed by, for example, a CVD process, a PECVD process, a HDP-CVD process, an ALD process, etc.

A second CMP process is performed on the first insulating interlayer 245. Thus, the first insulating interlayer 245 has a level upper face. In accordance with an exemplary embodiment of the present invention, the first insulating interlayer 245 may have a level upper face that is substantially higher than those of the gate structures 230. The second CMP process may be performed using the slurry composition that is substantially the same as that used in the first CMP process.

The first insulating interlayer 245 is partially etched to form first contact holes. The first insulating interlayer 245 may be etched by, for example, an anisotropic etching process. The first contact holes expose the first and second contact regions 235 and 240. The first contact holes may be formed by, for example, a self-alignment process. The first contact holes may be self-aligned relative to the gate structures 230. Some of the first contact holes expose the first contact region 235 corresponding to the capacitor contact region, and the rest of the first contact holes expose the second contact region 240 corresponding to the bit line contact region.

A second conductive layer is formed on the first insulating interlayer 245 to fill up the first contact holes. The second conductive layer may be formed using, for example, doped polysilicon, a metal or a conductive metal nitride.

The second conductive layer is partially removed until the first insulating interlayer 245 is exposed to form the first pad 250 and the second pad 255 in the first contact holes. The first and second pads 250 and 255 may be formed by, for example, a third CMP process or an etch-back process. The first pad 250 is formed on the first contact region 235 corresponding to the capacitor contact region, and the second pad 255 is formed on the second contact region 240 corresponding to the bit line contact region. Accordingly, the first and second pads 250 and 255 may make contact with the capacitor and the bit line contact regions, respectively.

A second insulating interlayer 260 is formed on the first insulating interlayer 245, the first pad 250 and the second pad 255. The second insulating interlayer 260 may electrically insulate the first pad 250 from a bit line 270 (see FIG. 10). In accordance with an exemplary embodiment of the present invention, the second insulating interlayer 260 may be formed using an oxide substantially the same as that of the first insulating interlayer 245. In accordance with another exemplary embodiment of the present invention, the second insulating interlayer 260 may be formed using an oxide different from that of the first insulating interlayer 245.

An upper portion of the second insulating interlayer 260 is planarized by performing a fourth CMP process. The fourth CMP process may use the slurry composition substantially the same as that used in the first CMP process. The planarized second insulating interlayer 260 is partially etched to form a second contact hole 265. The second contact hole 265 exposes the second pad 255 buried in the first insulating interlayer 245. The second contact hole 265 corresponds to a bit line contact hole where the bit line 270 (see FIG. 10) is formed.

Referring to FIG. 10, the bit line 270 is formed on the second insulating interlayer 260 to fill up the second contact hole 265. The bit line 270 makes contact with the second pad 255. In accordance with an exemplary embodiment of the present invention, the bit line may have a multi-layered structure that includes first and second layers. The first layer may be formed using, for example, a metal and/or a metallic compound, and a second layer may be formed using a metal. For example, the first layer may be formed using titanium and/or titanium nitride, and the second layer may be formed using tungsten.

A third insulating interlayer 275 is formed on the second insulating interlayer 260 to cover the bit line 270. In accordance with some exemplary embodiments of the present invention, the third insulating interlayer 275 may be formed using, for example, a silicon oxide substantially the same as that of the second insulating interlayer 260. Alternatively, the third insulating interlayer 275 may be formed using, for example, a silicon oxide that is different from that used in the second insulating interlayer 260.

An upper portion of the third insulating interlayer 275 is planarized by performing a fifth CMP process. In accordance with an exemplary embodiment of the present invention, an additional insulation layer may be further formed on the second insulating interlayer 260 to cover the bit line 270. The additional insulation layer may prevent a void from being generated in portions of the third insulating interlayer 275 that is located between adjacent bit lines 270. The additional insulation layer may be formed using, for example, a nitride.

The second and the third insulating interlayers 260 and 275 are partially etched to form third contact holes. The third contact holes expose the first pads 250. Each of the third contact holes corresponds to a capacitor contact hole.

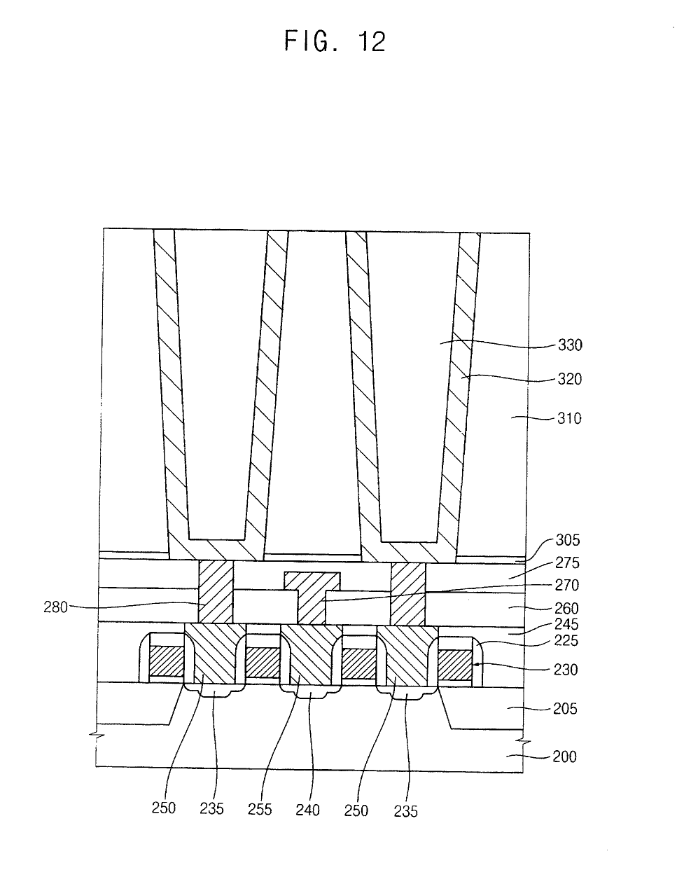

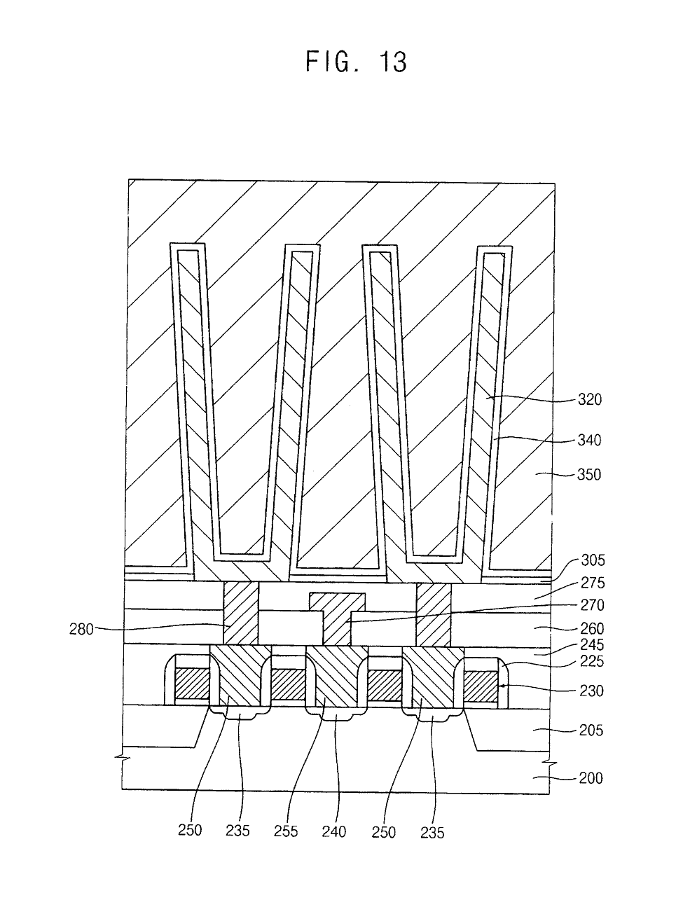

A fourth conductive layer is formed on the third insulating interlayer 275 to fill up the third contact holes. The fourth conductive layer is partially removed by a fifth CMP process, to thereby form third pads 280 in the third contact holes. The third pads 280 may be formed using polysilicon doped with impurities. The third pads 280 may electrically connect the first pads 250 to a lower electrode 320 (see FIG. 12) that is successively formed.

Referring to FIG. 11, an etch stop layer 305 is formed on the third pads 280 and the third insulating interlayer 275. The etch stop layer 305 may protect the third pads 280 during a successive etching process to form an opening 312 through a mold layer 310. The etch stop layer 305 may have a thickness of about 10 Å to about 200 Å. The etch stop layer 305 may be formed using a material that has an etching selectivity relative to a mold layer that is successively formed. For example, the etch stop layer 305 may be formed using nitride or metal oxide.

The mold layer is formed on the etch stop layer 305 using an oxide. For example, the mold layer may be formed using BPSG, PSG, USG, SOG, PE-TEOS, etc. The mold layer may be formed to have a thickness of about 10,000 Å to about 20,000 Å. However, the thickness of the mold layer may vary in accordance with the height of a capacitor, as the height of the capacitor may mainly depend on the thickness of the mold layer.

A mask pattern (not illustrated) is formed on the mold layer. The mold layer is partially etched using the mask pattern as an etching mask so as to form the opening 312 exposing the etch stop layer 305 through the mold layer. Then, the mold layer is formed into a mold layer pattern 310. The mold layer may be etched by an anisotropic etching process. The exposed etch stop layer 305 is partially etched to complete the opening 312 in a subsequent etching process. The opening 312 exposes the third pads 280.

Referring to FIG. 12, a lower electrode layer is formed on the third pads 280, a sidewall of the opening 312 and the mask pattern. The lower electrode layer may be formed using, for example, tungsten, titanium, tungsten nitride or titanium nitride. The lower electrode layer may have a thickness of about 300 Å to about 500 Å.

A sacrificial layer 330 is formed on the lower electrode layer to fill up the opening 312. For example, the sacrificial layer 330 may be formed using, for example, oxide or photoresist.

The sacrificial layer 330, the lower electrode layer and the mask pattern are removed by a sixth CMP process until the mold layer pattern 310 is exposed, and then the lower electrode 320 is formed on the third pads 280 and the sidewall of the opening 312. In accordance with an exemplary embodiment of the present invention, the lower electrode 320 may have a cylindrical structure as the opening 312 has a cylindrical shape. Here, the sacrificial layer 330 is formed on the lower electrode 320 to fill up the opening 312.

Referring to FIG. 13, the sacrificial layer 330 is selectively removed from the lower electrode 320, and the mold layer pattern 310 is selectively removed from the lower electrode 320 and the etch stop layer 305. Therefore, the lower electrode 320 making contact with the third pads 280 is protruded from the etch stop layer 305. A dielectric layer 340 is formed on the lower electrode 320.

In accordance with an exemplary embodiment of the present invention, the dielectric layer 340 may be formed using, for example, oxide, nitride, metal oxide, etc. In accordance with another exemplary embodiment of the present invention, the dielectric layer 340 may have a multi-layered structure that includes, for example, an oxide film and a nitride film, or a first oxide film, a nitride film and a second oxide film. In accordance with still another exemplary embodiment of the present invention, the dielectric layer 340 may be formed by, for example, an ALD process using metal oxide because the metal oxide has a low equivalent oxide thickness (EOT) and a low leakage current. For example, when the dielectric layer 340 is formed by the ALD process using metal oxide, the ALD process may be carried out at least once by performing a step of providing a reactant, a step of purging, a step of providing an oxidant, and a step of purging. Then, the dielectric layer 340 is formed on the lower electrode 320.

An upper electrode 350 is formed on the dielectric layer 340, and then a capacitor electrically connected to the substrate 200 is completed. The upper electrode 350 may be formed using, for example, polysilicon, metal or metal nitride. In accordance with an exemplary embodiment of the present invention, the upper electrode 350 may be formed using the metal nitride because the metal nitride may enhance an integration degree of a semiconductor device. For example, the upper electrode 350 may be formed by a CVD process using titanium nitride and a reaction gas including a titanium tetrachloride (TiCl₄) gas, an ammonium (NH₃) gas at a temperature below about 550° C.

According to exemplary embodiments of the present invention, although the slurry composition includes about 0.3 or less percent by weight of a ceria abrasive, the slurry composition has a high polishing rate for a silicon oxide layer and also a remarkably low polishing rate for a silicon nitride layer. Accordingly, the slurry composition may be effectively used in a polishing process for polishing a silicon oxide layer using a silicon nitride layer as a polish stop layer. Additionally, the silicon nitride layer may be successively polished to have an even surface and a uniform thickness using the slurry composition, after the silicon oxide layer is polished using the silicon nitride layer as the polish stop layer. Further, the slurry composition may be prepared at a cost that is about five times less than the cost required for preparing a conventionally used ceria slurry composition, and thus the slurry composition may be widely used in a process for manufacturing a semiconductor memory device.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A slurry composition for a chemical mechanical polishing process comprising:
about 0.05 to about 0.3 percent by weight of a ceria abrasive;
about 0.005 to about 0.04 percent by weight of an anionic surfactant;
about 0.0005 to about 0.003 percent by weight of a polyoxyethylene-based nonionic surfactant;
about 0.2 to about 1.0 percent by weight of a salt of polyacrylic acid having an average molecular weight substantially greater than a molecular weight of the anionic surfactant; and
a remainder of water.

2. The slurry composition of claim 1, wherein the anionic surfactant comprises at least one selected from the group consisting of carboxylic acid, a salt of carboxylic acid, sulfuric ester, a salt of sulfuric ester, sulfonic acid, a salt of sulfonic acid, phosphoric ester, a salt of phosphoric ester, and a salt of polyacrylic acid.

3. The slurry composition of claim 2, wherein the anionic surfactant comprises an ammonium salt of polyacrylic acid having an average molecular weight of about 2,000 to about 30,000.

4. The slurry composition of claim 1, wherein the polyoxyethylene-based nonionic surfactant comprises at least one selected from the group consisting of polyoxyethylene lauryl ether, polyoxyethylene cetyl ether, polyoxyethylene oleyl ether, polyoxyethylene sorbitan monolaurate, and polyoxyethylene isooctylphenyl ether.

5. The slurry composition of claim 1, wherein the slurry composition comprises:
about 0.1 to about 0.2 percent by weight of the ceria abrasive;
about 0.008 to about 0.02 percent by weight of the anionic surfactant;
about 0.0008 to about 0.002 percent by weight of the polyoxyethylene-based nonionic surfactant;
about 0.2 to about 0.9 percent by weight of the salt of polyacrylic acid; and
a remainder of water.

6. The slurry composition of claim 1, wherein the ceria abrasive has a particle size in a range of about 120 nanometers (nm) to about 200 nm.

7. The slurry composition of claim 1, wherein the salt of polyacrylic acid comprises an ammonium salt of polyacrylic acid having an average molecular weight of about 100,000 to about 400,000.

8. The slurry composition of claim 1, wherein the slurry composition has a pH value in a range of about 6 to about 9.

9. A method of polishing an object layer comprising:
forming an object layer on a substrate to cover a polish stop layer; and
polishing the object layer by bringing the object layer in contact with a polishing pad while a slurry composition is provided to the polishing pad until the polish stop layer is exposed, the slurry composition including about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to about 1.0 percent by weight of a salt of polyacrylic acid having an average molecular weight substantially greater than a molecular weight of the anionic surfactant, and a remainder of water.

10. The method of claim 9, wherein the polish stop layer comprises a silicon nitride layer and the object layer comprises a silicon oxide layer.

11. The method of claim 9, wherein a polishing selectivity between the polish stop layer and the object layer is in a range of about 1:25 to about 1:40.

12. The method of claim 9, wherein the anionic surfactant comprises an ammonium salt of polyacrylic acid having an average molecular weight of about 2,000 to about 30,000.

13. The method of claim 9, wherein the slurry composition comprises:
about 0.1 to about 0.2 percent by weight of the ceria abrasive;
about 0.008 to about 0.02 percent by weight of the anionic surfactant;
about 0.0008 to about 0.002 percent by weight of the polyoxyethylene-based nonionic surfactant;
about 0.2 to about 0.9 percent by weight of the salt of polyacrylic acid; and
a remainder of water.

14. A method of manufacturing a semiconductor memory device comprising:
forming a nitride layer pattern on a substrate;
partially etching the substrate using the nitride layer pattern as an etching mask to form a trench at an upper portion of the substrate;
forming a silicon oxide layer on the substrate to cover the nitride layer pattern and to fill up the trench;
polishing the silicon oxide layer using a slurry composition until the nitride layer pattern is exposed to form an isolation layer on the substrate, the slurry composition including about 0.05 to about 0.3 percent by weight of a ceria abrasive, about 0.005 to about 0.04 percent by weight of an anionic surfactant, about 0.0005 to about 0.003 percent by weight of a polyoxyethylene-based nonionic surfactant, about 0.2 to about 1.0 percent by weight of a salt of polyacrylic acid having an average molecular weight substantially greater than a molecular weight of the anionic surfactant, and a remainder of water; and
forming a structure on the substrate including the isolation layer, the structure including a gate insulation layer and a conductive pattern.

15. The method of claim 14, wherein the anionic surfactant comprises polyacrylic acid, a salt of polyacrylic acid or sodium dodecylsulfonate.

16. The method of claim 14, wherein the slurry composition has a pH value in a range of about 6 to about 9.

17. The method of claim 14, further comprising removing the nitride layer pattern from the substrate, after polishing the silicon oxide layer to form the isolation layer on the substrate.
